(19) United States
(12) Patent Application Publication
(10) Pub. No.: US 2020/0203144 A1
(43) Pub. Date: Jun. 25, 2020

(54) METHODS OF CLEANING AN OXIDE LAYER IN A FILM STACK TO ELIMINATE ARCING DURING DOWNSTREAM PROCESSING

(71) Applicant: APPLIED MATERIALS, INC., Santa Clara, CA (US)

(72) Inventors: CHAO DU, SUNNYVALE, CA (US); VAIBHAV SONI, SUNNYVALE, CA (US); LIN TL, SANTA CLARA, CA (US); YONG CAO, SAN JOSE, CA (US); MINGDONG LI, SANTA CLARA, CA (US); MINGTE LIU, SAN JOSE, CA (US); CHEN GONG, SUNNYVALE, CA (US); XIAODONG WANG, SAN JOSE, CA (US); RONGJUN WANG, DUBLIN, CA (US); XIANMIN TANG, SAN JOSE, CA (US)

(21) Appl. No.: 16/370,399

(22) Filed: Mar. 29, 2019

Related U.S. Application Data
(60) Provisional application No. 62/784,220, filed on Dec. 21, 2018.

(51) Int. Cl. H01L 21/02

(52) U.S. Cl. CPC H01L 21/0206; H01L 21/02186; H01L 21/02126; H01L 21/022; H01L 21/02164

(57) ABSTRACT

Methods and apparatus for reducing arcing of a silicon oxide layer in a film stack are provided. In some embodiments a method for reducing arcing of a silicon oxide layer in a film stack includes: depositing a silicon oxide layer having a top surface atop a low-k dielectric layer, wherein the silicon oxide layer and low-k dielectric layer are disposed upon a substrate and within a film stack; contacting the silicon oxide layer with argon plasma in an amount sufficient to clean the silicon oxide layer; and depositing a nitride layer atop the silicon oxide layer.

### CROSS-REFERENCE TO RELATED APPLICATIONS

This application claims benefit of U.S. provisional patent application Ser. No. 62/784,220, filed Dec. 21, 2018, which is herein incorporated by reference in its entirety.

### FIELD

Embodiments of the present disclosure generally relate to electronic device processing, and more particularly, reducing arcing of one or more layers within a film stack such as a film stack subjected to high-pressure downstream processing.

### BACKGROUND

Microelectronic devices are generally fabricated on a semiconductor substrate as integrated circuits wherein various conductive layers are interconnected to one another to facilitate propagation of electronic signals within the device. Such devices may include, for example, transistors such as complementary metal-oxide-semiconductor (CMOS) field effect transistors or storage elements in memories such as magneto-resistive random access memories (MRAM) that facilitate storage of digital information.

Integrated circuits in the 10/7 nm nodes and beyond typically include layers of material deposited as overlying blanket films to form film stacks, and patterned to form a desired semiconductor device. Patterning of a semiconductor device may include use of a hard mask in which one or more layers are added to a film stack during fabrication. The inventors have observed that layers in a semiconductor film stack such as thin oxide films are not stable during downstream processing such as patterning under high pressure conditions and may be easily warped or damaged during device fabrication or use thereof. For example, arcing of a layer within a film stack problematically decreases productivity and increases the cost of fabricating the semiconductor devices. Moreover, the inventors have observed contamination on a substrate prior to hard mask application thereto and contamination within a process chamber problematically promotes arcing of layers within the semiconductor device.

Therefore, the inventors believe that there is a need in the art for improved methods of fabricating film stacks such as those used in integrated circuits in the 10/7 nm nodes and beyond and for oxide layers in semiconductor film stacks with a durability sufficient to withstand typical integrated circuit or MRAM processing such as hard mask deposition under high pressure conditions.

Accordingly, the inventors have provided improved methods and apparatus for depositing materials via physical vapor deposition.

### SUMMARY

Methods and apparatus for forming a semiconductor structure are provided herein. In some embodiments, a method for forming a semiconductor structure, includes: depositing an oxide layer having a top surface atop a low-k dielectric layer, wherein the oxide layer and low-k dielectric layer are disposed upon a substrate and within a film stack; and contacting the oxide layer with argon plasma in an amount sufficient to clean the oxide layer.

In some embodiments, a method of cleaning an oxide layer in a film stack, includes: contacting an oxide layer disposed atop a low-k dielectric layer with argon plasma under conditions sufficient to clean the oxide layer, wherein the oxide layer and low-k dielectric layer are disposed upon a substrate and within a film stack.

In some embodiments, a method of reducing arcing of an oxide layer in a film stack, includes: contacting an oxide layer disposed atop a low-k dielectric layer with argon plasma under conditions sufficient to clean the oxide layer, wherein the oxide layer and low-k dielectric layer are disposed upon a substrate and within a film stack.

In some embodiments, a method of reducing arcing of a silicon oxide layer in a film stack, includes: depositing a silicon oxide layer having a top surface atop a low-k dielectric layer, wherein the silicon oxide layer and low-k dielectric layer are disposed upon a substrate and within a film stack; contacting the silicon oxide layer with argon plasma in an amount sufficient to clean the silicon oxide layer; and depositing a nitride layer atop the silicon oxide layer.

In some embodiments, a method of cleaning an oxide layer in a film stack, includes: contacting a silicon oxide layer disposed atop a silicon oxycarbide low-k dielectric layer with argon plasma under conditions sufficient to clean the silicon oxide layer, wherein the silicon oxide layer and silicon oxycarbide low-k dielectric layer are disposed upon a substrate and within a film stack.

In some embodiments, a method of forming a semiconductor film stack, includes: contacting a silicon oxide layer disposed atop a silicon oxycarbide low-k dielectric layer with argon plasma under conditions sufficient to clean the silicon oxide layer, wherein the silicon oxide layer and silicon oxycarbide low-k dielectric layer are disposed upon a substrate and within a film stack.

Other and further embodiments of the present disclosure are described below.

### BRIEF DESCRIPTION OF THE DRAWINGS

Embodiments of the present disclosure, briefly summarized above and discussed in greater detail below, can be understood by reference to the illustrative embodiments of the disclosure depicted in the appended drawings. However, the appended drawings illustrate only typical embodiments of the disclosure and are therefore not to be considered limiting of scope, for the disclosure may admit to other equally effective embodiments.

FIG. 1 is a flow diagram of a method of making a semiconductor film stack in accordance with one embodiment of the present disclosure;

FIGS. 2A-2B depict a series of schematic, cross-sectional views of a substrate having a film stack being formed in accordance with the method of FIG. 1;

FIG. 3 depicts a process chamber suitable for argon treatment in accordance with the present disclosure;

FIG. 4 is a flow diagram of a method of cleaning an oxide layer in a film stack of the present disclosure;

FIG. 5 is a flow diagram of a method of reducing arcing of an oxide layer in a film stack in accordance with the present disclosure;

FIG. 6 is a flow diagram of a method of reducing arcing of a silicon oxide layer in a film stack in accordance with the present disclosure;

FIG. 7 is a flow diagram of a method of cleaning a silicon oxide layer in a film stack in accordance with the present disclosure; and

FIG. 8 is a flow diagram of a method of forming a semiconductor film stack in accordance with the present disclosure.

To facilitate understanding, identical reference numerals have been used, where possible, to designate identical elements that are common to the figures. The figures are not drawn to scale and may be simplified for clarity. Elements and features of one embodiment may be beneficially incorporated in other embodiments without further recitation.

### DETAILED DESCRIPTION

Embodiments for forming a semiconductor structure are provided herein. In some embodiments, a method for forming a semiconductor structure, includes: depositing an oxide layer having a top surface atop a low-k dielectric layer, wherein the oxide layer and low-k dielectric layer are disposed upon a substrate and within a film stack; and contacting the oxide layer with argon plasma in an amount sufficient to clean the oxide layer. The methods of the present disclosure treat and stabilize oxide films sufficient to withstand stressful downstream processing under high pressure conditions thus desensitize films to high pressure deposition of one or more hard mask layers. The treatments of the present disclosure protect films in a film stack from being easily warped or damaged during device fabrication or use thereof. For example, treatment in accordance with the present disclosure suppress or eliminate arcing within a film stack increasing productivity and decreasing the cost of fabricating the semiconductor devices. Moreover, the inventors have observed cleaning of a film stack component and removing contamination such as arching source on a substrate prior to hard mask application reduces or eliminates problematic arcing of an oxide layer during production while maintaining desirable film properties.

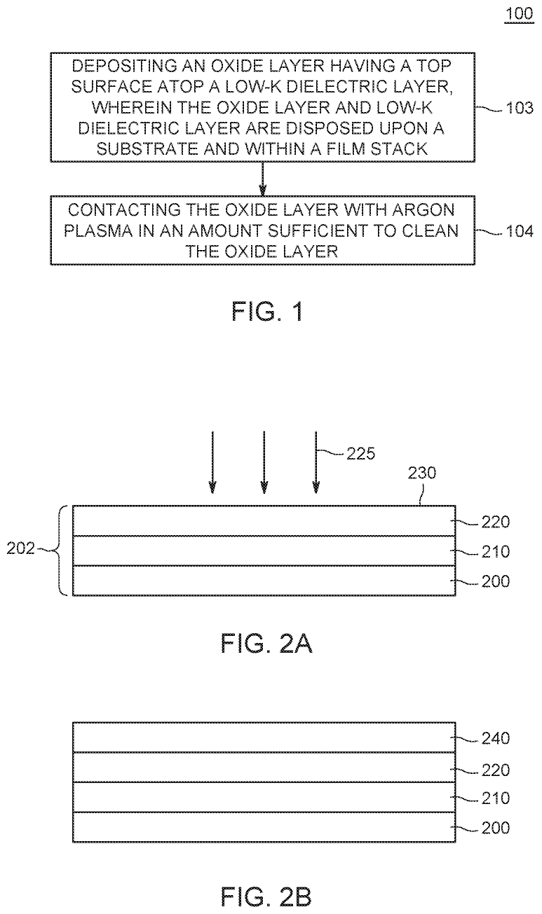

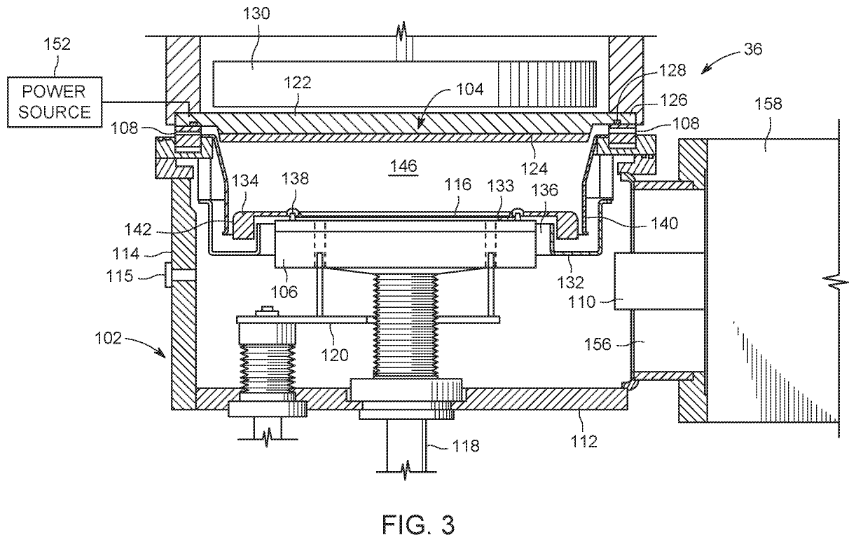

FIG. 1 is a flow diagram of one embodiment of a method for forming a semiconductor structure in accordance with one embodiment of the present disclosure as sequence 100. The sequence 100 includes the processes that are performed upon film stack during fabrication of such semiconductor device. FIGS. 2A-2B depict a series of schematic, cross-sectional views of a substrate including a semiconductor device being formed using the sequence 100. The images in FIGS. 2A-2B are not depicted to scale and are simplified for illustrative purposes. The methods of the present disclosure may be performed in process chambers configured for physical vapor deposition (PVD) such as the process chamber discussed below with respect to FIG. 3.

In some embodiments, the sequence 100 for forming a film stack 202 (FIG. 2A) on substrate 200 may start at 103 by depositing an oxide layer having a top surface atop a low-k dielectric layer, wherein the oxide layer and low-k dielectric layer are disposed upon a substrate and within a film stack. In embodiments, the substrate 200 may comprise a material such as crystalline silicon (e.g., Si<100> or Si<111>), silicon germanium, doped or undoped polysilicon, doped or undoped silicon wafers, patterned or non-patterned wafers, silicon on insulator (SOI), carbon doped silicon oxides, silicon nitride, doped silicon, germanium, gallium arsenide, glass, sapphire, and combinations thereof. In embodiments, the substrate 200 may have various dimensions, such as 200 mm, 300 mm, 450 mm or other diameters for round substrates. The substrate 200 may also be any polygonal, square, rectangular, curved or otherwise non-circular workpiece, such as a polygonal glass substrate used in the fabrication of flat panel displays. Unless otherwise noted, implementations and examples described herein are conducted on substrates such as substrate 200 with a 200 mm diameter, a 300 mm diameter, or a 450 mm diameter substrate. In embodiments, the substrates may be planar, or substantially planar. For example, in embodiments, a substrate may include a planar or substantially planar lower surface of the substrate in parallel orientation with an upper surface of the substrate.

In embodiments, low-k dielectric layer 210 is deposited atop substrate 200 via any suitable atomic layer deposition process or a chemical layer deposition process to a thickness sufficient to insulate film stack 202. In embodiments, the low-k dielectric layer 210 may be planar, or substantially planar. For example, in embodiments, a low-k dielectric layer 210 may include a planar or substantially planar lower surface of the low-k dielectric layer 210 in parallel orientation or substantially parallel orientation with an upper surface of the low-k dielectric layer 210. In embodiments, the low-k dielectric layer 210 is generally formed from a material having a low-k value suitable for insulating material and sufficient to separate interconnects. In embodiments, low-k dielectric layer 210 is made of a material and provided at a thickness sufficient to reduce charge build-up in film stack 202. In embodiments, the low-k dielectric layer 210 comprises material including one or more of polyimides, polytetrafluoroethylenes, parylenes, polysilsesquioxanes, fluorinated poly(aryl ethers), fluorinated amorphous carbon, silicon oxycarbides, and silicon carbides. In embodiments, low-k dielectric layer 210 may be deposited on a substrate by reacting a processing gas in a plasma to form a dielectric layer having a dielectric constant less than about 4. In embodiments, a dopant-containing gas may also be present during the reaction or deposition of the low-k dielectric layer 210. The processing gas may also include nitrogen (N₂) or an inert gas, such as argon (Ar) or helium (He), or combinations thereof.

In embodiments, the low-k dielectric layer 210 comprises silicon oxycarbides, the silicon oxycarbides may comprise various silicon, carbon, oxygen, and hydrogen containing materials. For example, the silicon oxycarbides may comprise silicon oxycarbides, such as BLACK DIAMOND™ brand film, available from Applied Materials, Inc., Santa Clara, Calif. A method for depositing silicon oxycarbides is described in U.S. Pat. No. 6,287,990, entitled, “CVD Plasma Assisted Low Dielectric Constant Films,” assigned to Applied Materials, Inc.

In embodiments, film stack 202 comprises an oxide layer such as oxide layer 220 having a top surface 230 shown in FIG. 2A. In embodiments, oxide layer 220 is deposited atop low-k dielectric layer 210 via any suitable atomic layer deposition process or a chemical layer deposition process to a thickness sufficient to cover the low-k dielectric layer 210 in film stack 202. In embodiments, oxide layer 220 may be formed to any suitable thickness using any suitable technique that may depend, for instance, on the material or materials used. In embodiments, the oxide layer 220 may be planar, or substantially planar. For example, in embodiments, an oxide layer 220 may include a planar or substantially planar lower surface of the oxide layer 220 in parallel orientation or substantially parallel orientation with an upper surface of the oxide layer 220. In embodiments, the oxide layer 220 may be flat or substantially flat. In embodiments, oxide layer 220 comprises one or more organic polymers, organic materials, or metal materials. In embodiments, oxide layer 220 is an organic film, or a polymer with silicon disposed therein. In embodiments, the oxide layer 220 comprises an oxide layer made from organosilicon compounds such as tetraethyl orthosilicate or TEOS deposited as a planar film by a chemical vapor deposition (CVD) techniques, such as high density plasma chemical vapor deposition (HDP-CVD), low pressure chemical vapor deposition (LPCVD) or plasma enhanced chemical vapor deposition (PECVD). In embodiments, oxide layer 220 has a thickness suitable for functioning as a hard mask for etching one or more underlying layers. In one embodiment, the oxide layer 220 has a thickness from about 2,000 angstroms to about 5,000 angstroms. In embodiments, the oxide layer is silicon oxide, silicon dioxide, or combinations thereof.

Returning to FIG. 1, at 104, the process sequence includes contacting the oxide layer 220 with argon plasma (shown as arrow 225 in FIG. 2A) in an amount sufficient to clean the oxide layer 220 and top surface 230 of the oxide layer 220. In embodiments, contacting the oxide layer 220 with argon plasma in an amount sufficient to clean the oxide layer 220 includes contacting the oxide layer 220 with argon plasma wherein argon is supplied to the substrate (in a process chamber such as chamber enclosure 102) at a flow rate between 50 and 150 sccm. in embodiments, contacting the oxide layer 220 with argon plasma is performed with argon supplied to the substrate at a flow rate between 50 and 150 sccm. In embodiments, contacting the oxide layer with argon plasma is performed with a bias power of 75 to 150 watts applied to the substrate. In embodiments, contacting the oxide layer with argon plasma is performed with at a pressure of about 30 to about 50 milliTorr. In embodiments, contacting the oxide layer with argon plasma is performed for a duration of 5 seconds to about 1 minute. Referring to FIG. 3, chamber enclosure 102 may be provided to facilitate, promote, or maintain process conditions as described herein. In embodiments, the process sequence includes contacting the oxide layer 220 with argon plasma (shown as arrow 225 in FIG. 2A) in an amount sufficient to clean, such as removing all or substantially all arcing source contaminant from, the oxide layer 220 and/or top surface 230 of the oxide layer 220.

In embodiments, the methods of the present disclosure are suitable wherein oxide layer 220 contacted with argon plasma in accordance with the present disclosure is subjected to further processing such as hard mask layer deposition upon oxide layer 220 and etching of the film stack 202 under high pressure conditions. Accordingly, embodiments, of the present disclosure, although not shown in FIG. 1, include subsequently depositing a nitride layer 240 such as titanium nitride, silicon nitride, and the like atop oxide layer 220. In embodiments, the methods of the present disclosure are useful where a nitride layer 240 (FIG. 2B) is deposited atop the oxide layer 220 under stressful conditions to the oxide layer 220 such as a pressure of about 150 to about 400 milliTorr or about 300 to about 400 milliTorr; under a power of about 18 to about 30 kilowatts; and/or at a temperature greater than 350 degrees Celsius.

In embodiments, nitride layer 240 may be formed directly atop oxide layer 220. The nitride layer 240 can be formed using any suitable PVD technique known in the art.

In embodiments, after application of nitride layer 240, the film stack incudes a hard mask sufficient for further processing such as etching. in embodiments, the nitride layer 240 has a thickness suitable for functioning as a hard mask for etching the underlying oxide layer 220. In embodiments, the nitride layer 240 has a thickness from about 500 angstroms to about 5,000 angstroms, from about 1,000 angstroms to about 4,000 angstroms, or a thickness from about 1,500 angstroms to about 3,000 angstroms.

Referring now to FIG. 3, a schematic cross-sectional view of a PVD chamber suitable for performing the processes of the present disclosure is shown. For example, the methods of the present disclosure may be performed using a PVD chamber commercially available from Applied Materials, Inc., of Santa Clara, Calif.. The features of a suitable PVD chamber are generally described below. However, while the below described PVD chamber is suitable for use in accordance with the methods of the present disclosure, other chambers may also be used or modified to be used, to advantage to accomplish the methods of the present disclosure. For example, a vacuum preclean chamber, such as a Siconi Preclean chamber, or Applied Materials type PC XT or PC XTe pre-dean chambers available from Applied Materials Inc. of Santa Clara, Calif. may be used. In alternative embodiments, other chamber types can be used.

Referring to FIG. 3, a PVD chamber 36 generally includes a chamber enclosure 102, a target 104, a substrate support 106, a gas inlet 108 and a gas exhaust 110. The chamber enclosure 102 includes a chamber bottom 112 and a chamber sidewall 114. A slit valve 115 is disposed on a chamber sidewall 114 to facilitate transfer of a substrate 116 into and out of the PVD chamber 36. The substrate support 106 is disposed on a substrate support lift assembly 118 through the chamber bottom 112. Typically, a temperature control element (not shown), such as a heater, is incorporated within the substrate support 106 to control the temperature of the substrate 116 during processing. In some embodiments, the substrate support 106 is made of stainless steel, and the temperature control element comprises a platinum/rhodium heater coil. The substrate support lift assembly 118 moves the substrate support 106 vertically between a substrate transfer position and a substrate processing position. A lift pin assembly 120 lifts the substrate 116 off the substrate support 106 to facilitate transfer of the substrate 116 between the chamber and a robot bade (not shown) used to transfer the substrate into and out of the chamber.

In embodiments, target 104 is disposed in the top portion of the chamber enclosure 102. In embodiments, the target 104 is positioned directly above the substrate support 106. The target 104 generally comprises a backing plate 122 supporting a plate of sputterable material 124. In embodiments, a typical target material for nitride films may include titanium for use with a reactive sputtering process. The backing plate 122 includes a flange portion 126 that is secured to the chamber enclosure 102. In embodiments, a seal 128, such as an O-ring, is provided between the flange portion 126 of the backing plate 122 and the chamber enclosure 102 to establish and maintain a vacuum environment in the chamber during processing. A magnet assembly 130 is disposed above the backing plate 122 to provide magnetic field enhancement that increases the plasma density adjacent the target sputtering surface (by trapping electrons) to enhance sputtering of the target material.

In embodiments, a lower shield 132 is disposed in the chamber to shield the interior surfaces of the chamber enclosure 102 from deposition. The lower shield 132 extends from the upper portion of the chamber sidewall 114 to a peripheral edge of the substrate support 106 in the processing position. A damp ring 134 may be used and is removeably disposed on an inner terminus 136 of the lower shield 132. When the substrate support 106 moves into the processing position, the inner terminus 136 surrounds the substrate support 106, and a peripheral portion 138 of the substrate 116 engages an inner terminus 133 of the damp ring 134 and lifts the damp ring 134 off the inner terminus 136 of the lower shield 132. The damp ring 134 serves to damp or hold the substrate 116 as well as shield the peripheral portion 138 of the substrate 116 during the deposition process. Alternatively, instead of a damp ring 134, a shield cover ring (not shown) is disposed above an inner terminus of the lower shield. When the substrate support moves into the processing position, the inner terminus of the shield cover ring is positioned immediately above the peripheral portion of the substrate to shield the peripheral portion of the substrate support 106 from deposition.

In some embodiments, an upper shield 140 is disposed within an upper portion of the lower shield 132 and extends from the upper portion of the chamber sidewall 114 to a peripheral edge 142 of the clamp ring 134. In embodiments, the upper shield 140 comprises a material that is similar to the materials that comprise the target, such as titanium and other metals. In some embodiments, the upper shield 140 is a floating-ground upper shield that provides an increased ionization of the plasma compared to a grounded upper shield. The increased ionization provides more ions to impact the target 104 leading to a greater deposition rate because of the increased sputtering from the target 104. Alternatively, the upper shield 140 can be grounded during the deposition process.

A gas inlet 108 disposed in the chamber sidewall 114 of the chamber enclosure 102 introduces a processing gas into the chamber enclosure 102 and enters a process cavity 146 by flowing between the upper shield 140 and the lower shield 132. The process cavity 146 is defined by the target 104, the substrate 116 disposed on the substrate support 106 in the processing position and the upper shield 140. In embodiments, argon is introduced through the gas inlet 108 as the process gas source for the plasma. A gas exhaust 110 is disposed on the chamber sidewall 114 to evacuate the chamber prior to the deposition process, as well as control the chamber pressure during the deposition process. In embodiments, the gas exhaust 110 includes an exhaust valve 156 and an exhaust pump 158. The exhaust valve 156 controls the conductance between the interior of the PVD chamber 36 and the exhaust pump 158.

To supply a bias to the target 104, a power source 152 is electrically connected to the target 104. The power source 152 may include a DC generator and a DC matching network coupled to the target 104. The power source 152 supplies the energy to the process cavity to strike and maintain a plasma of the processing gas in the process cavity during a cleaning process as described herein or a deposition process.

A gas exhaust 110 is disposed on the chamber sidewall 114 to evacuate the chamber prior to the deposition process, as well as control the chamber pressure during the deposition process. In embodiments, the gas exhaust 110 Includes an exhaust valve 156 and an exhaust pump 158. The exhaust valve 156 controls the conductance between the interior of the PVD chamber 36 and the exhaust pump 158. The exhaust pump 158 may comprise a turbomolecular pump in conjunction with a cryopump to minimize the pump down time of the chamber. Alternatively, the exhaust pump 158 comprises a low pressure, a high pressure pump or a combination of low pressure and high pressure pumps.

In embodiments, the cleaning process is performed in a processing zone or process cavity 146 located between the sputtering target 104. in embodiments, composed of titanium, and the substrate 116 including a carbon containing layer such as tetraethyl orthosilicate or TEOS. In embodiments, the target 104 may be electrically isolated from the PVD chamber 36 and serves as a process electrode for generating a sputtering plasma, During a cleaning process, a plasma, typically sourced from a noble gas such as argon, is introduced into the process cavity 146 of the FVD chamber 36 at a flow rate between 50 and 150 sccm, such as 100 sccm. In embodiments, 75 to 150 watts bias, such as 100 watts bias is applied to the substrate at about 30 to 50 milliTorr for a duration of 5 seconds to about 1 minute. In some embodiments, such as a TiN deposition, power is supplied to the sputtering target 104, with the target at a negative voltage, to form an electric field within the PVD chamber 36, with the chamber walls, and if desired, the substrate support 106 disposed in the FVD chamber 36 being electrically grounded. The resultant electric field in the PVD chamber 36 ionizes the sputtering gas such as argon to form a sputtering plasma that sputters the target 104 causing deposition of material on the substrate. In the sputtering processes, the plasma is typically generated by applying a DC or RF voltage at a power level to the sputtering target of from about 100 to about 20,000 watts, and more typically from about 100 to 10,000 watts, and in some embodiments between about 4000 and about 7000 watts.

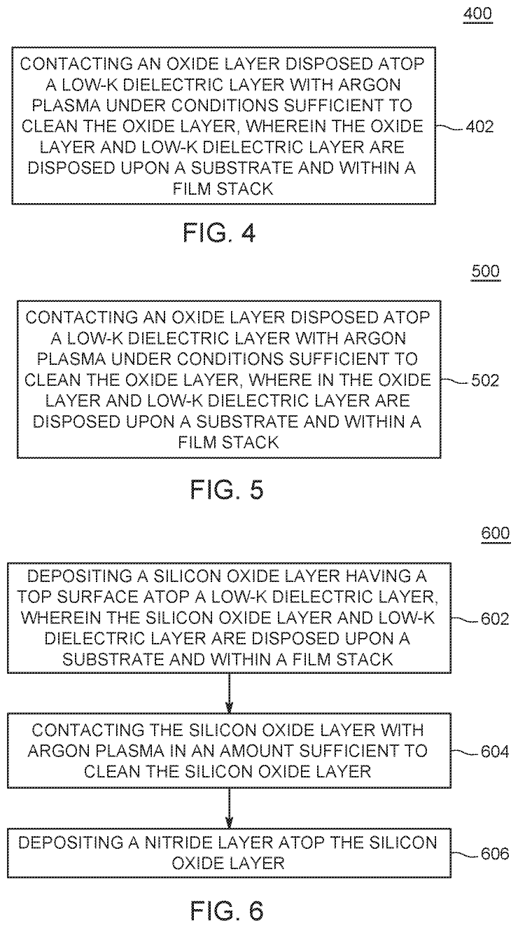

FIG. 4 is a flow diagram of a method of cleaning an oxide layer 220 in a film stack 202 of the present disclosure. In embodiments, at process sequence 402, a method of cleaning an oxide layer 220 in a film stack 202, includes: contacting an oxide layer disposed atop a low-k dielectric layer with argon plasma under conditions sufficient to clean the oxide layer, wherein the oxide layer and low-k dielectric layer are disposed upon a substrate and within a film stack. In embodiments, cleaning the oxide layer refers to removing arcing sources or substantially all arcing sources from the oxide layer, and/or top surface of the oxide layer. In embodiments, the oxide layer 220 comprises a planar film of tetraethyl orthosilicate or silicon oxide formed therefrom. In embodiments, contacting the oxide layer with argon plasma is performed with a bias power of 75 to 150 watts applied to the substrate. In embodiments, contacting the oxide layer with argon plasma is performed with at a pressure of about 30 to about 50 milliTorr, for a duration of 5 seconds to about 1 minute, wherein argon is supplied to the substrate at a flow rate between 50 and 150 sccm. In some embodiments, contacting the top surface 230 of the oxide layer 220 with argon plasma includes an amount of argon plasma sufficient to clean the oxide layer 220 including an amount sufficient to clean the oxide layer 220 to suppress or eliminate arcing of one or more layers such as oxide layer 220 within a film stack such as film stack 202 when a film stack is subjected to high-pressure downstream processing e.g., deposition of a nitride layer hard mask. In embodiments, the oxide layer is silicon oxide or silicon dioxide. In some embodiments, contacting the top surface 230 of the oxide layer 220 with argon plasma includes an amount of argon plasma sufficient to remove a portion of oxide layer 220 such as about 5-15 angstroms of material across the top surface of oxide layer 220. In some embodiments, contacting the top surface 230 of the oxide layer 220 with argon plasma includes an amount of argon plasma sufficient to remove a portion of oxide layer 220 such as about 5-15 angstroms of material across the top surface of oxide layer 220 by contacting with argon plasma in an amount sufficient to remove a top portion of the oxide layer 220 to suppress or eliminate arcing of one or more layers such as oxide layer 220 within a film stack 202 when a film stack is subjected to high-pressure downstream processing e.g., deposition of a nitride layer hard mask. In embodiments, the oxide layer is silicon oxide or silicon dioxide.

FIG. 5 is a flow diagram of a method of reducing arcing of an oxide layer in a film stack. In embodiments, at process sequence 502 a method of reducing arcing of an oxide layer in a film stack 202, includes: contacting an oxide layer 220 disposed atop a low-k dielectric layer 210 with argon plasma (e.g., arrow 225) under conditions sufficient to clean the oxide layer, wherein the oxide layer and low-k dielectric layer are disposed upon a substrate 200 and within a film stack 202. In embodiments, the oxide layer 220 comprises a planar film or substantially planar film of tetraethyl orthosilicate or silicon oxide formed from tetraethyl orthosilicate, and the like. In embodiments, contacting the oxide layer 220 with argon plasma is performed with a bias power of 75 to 150 watts applied to the substrate. In embodiments, contacting the oxide layer 220 with argon plasma is performed with at a pressure of about 30 to about 50 milliTorr. for a duration of 5 seconds to about 1 minute, wherein argon is supplied to the substrate at a flow rate between 50 and 150 sccm. In some embodiments, contacting the oxide layer 220 with argon plasma includes an amount of argon plasma sufficient to clean the oxide layer 220. In some embodiments, an amount sufficient to clean the oxide layer 220 includes amounts to suppress or eliminate arcing of one or more layers such as oxide layer 220. For example, arching of oxide layer 220 is reduced or eliminated within a film stack 202 when a film stack is subjected to high-pressure downstream processing, e.g., deposition of a nitride layer hard mask. Referring to FIGS. 2A and 2B, oxide layer 220 is shown as flat or substantially flat within the film stack such as a film stack including nitride layer 240 deposited atop or directly atop the oxide layer 220. In embodiments, reducing arcing may refer to maintaining a flat layer or film such as a flat or substantially flat oxide layer such as oxide layer 220 with nitride layer 240 deposited atop or directly atop oxide layer 220 in accordance with the present disclosure. In embodiments, reducing arcing of an oxide layer may refer to maintaining the oxide layer in a planar, or substantially planar shape. For example, in embodiments, the oxide layer is maintained in a planar or substantially planar shape where the lower surface of the oxide layer is in parallel orientation or substantially parallel orientation with an upper surface of the oxide layer when a nitride layer 240 is deposited atop or directly atop oxide layer 220 in accordance with the present disclosure. In embodiments, reducing arcing of an oxide layer may refer to maintaining the oxide layer in a planar, or substantially planar shape, for example the oxide layer is maintained in a planar or substantially planar shape where the entire lower surface of the oxide layer is in parallel orientation or substantially parallel orientation with the entire upper surface of the oxide layer, and the lower and upper surface are in parallel orientation or substantially parallel orientation to a substrate plane.

FIG. 6 is a flow diagram of a method 600 of reducing arcing of a silicon oxide layer in a film stack in accordance with the present disclosure. In embodiments, method 600 includes at process sequence 602 depositing a silicon oxide layer having a top surface atop a low-k dielectric layer, wherein the silicon oxide layer and low-k dielectric layer are disposed upon a substrate and within a film stack. In some embodiments, the silicon oxide layer includes silicon oxide or silicon dioxide formed from an organosilicon compound such as tetraethyl orthosilicate or TEOS. In some embodiments, the silicon oxide layer is a planar film or a substantially planar film within a semiconductor film stack. In embodiments, the silicon oxide layer is essentially planar on at least one surface, or is entirely planar.

In embodiments, method 600 includes at process sequence 604 contacting the silicon oxide layer with argon plasma in an amount sufficient to clean the silicon oxide layer. In some embodiments, contacting the silicon oxide layer with argon plasma is performed with a bias power of 75 to 150 watts applied to the substrate. In some embodiments, contacting the silicon oxide layer with argon plasma is performed with at a pressure of about 30 to about 50 milliTorr. In some embodiments, contacting the silicon oxide layer with argon plasma is performed for a duration of 5 seconds to about 1 minute. In some embodiments, contacting the silicon oxide layer with argon plasma is performed with argon supplied to the substrate at a flow rate between 50 and 150 sccm.

In embodiments, method 600 includes at process sequence 606 depositing a nitride layer atop the silicon oxide layer. In embodiments, subsequent to depositing the nitride layer atop the silicon oxide layer, the silicon oxide layer is a planar or substantially planar film. For example, in embodiments, the silicon oxide layer is maintained in a planar or substantially planar shape where the lower surface of the silicon oxide layer is in parallel orientation or substantially parallel orientation with an upper surface of the silicon oxide layer. In another example, referring to FIGS. 2A and 2B, oxide layer 220 (shown in cross-section) includes the top surface 230 as substantially planar as shown and described, without warping or dishing, or substantial changes in thickness. In embodiments, substantially planar may refer to a substantially flat layer such as e.g., oxide layer 220 in FIG. 2B. In some embodiments, the nitride layer is titanium nitride. In embodiments, the nitride layer is deposited atop the silicon oxide layer at a pressure of about 300 to about 400 milliTorr. In embodiments, the nitride layer is deposited atop the silicon oxide layer at a pressure of about 150 to about 400 milliTorr or about 300 to about 400 milliTorr. In embodiments, the nitride layer is deposited atop the silicon oxide layer under a power of about 18 to about 30 kilowatts. In embodiments, the nitride layer is deposited atop the silicon oxide layer at a temperature greater than 350 degrees Celsius.

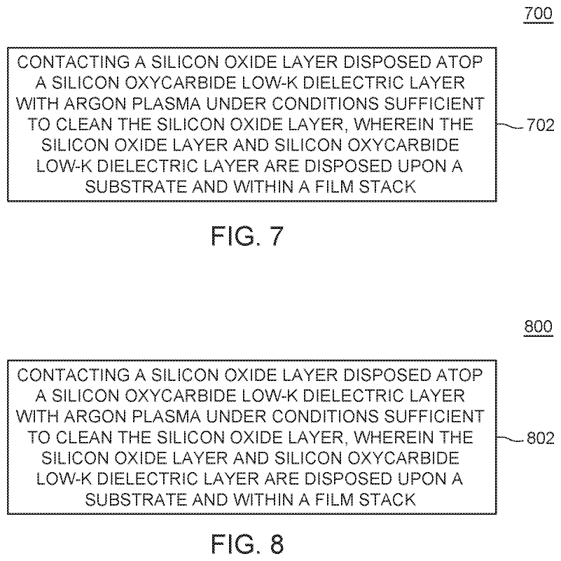

FIG. 7 is a flow diagram of a method 700 of cleaning a silicon oxide layer in a film stack in accordance with the present disclosure. In embodiments, method 700 includes at process sequence 702 contacting a silicon oxide layer disposed atop a silicon oxycarbide low-k dielectric layer with argon plasma under conditions sufficient to clean the silicon oxide layer, wherein the silicon oxide layer and silicon oxycarbide low-k dielectric layer are disposed upon a substrate and within a film stack. In embodiments, the silicon oxide layer comprises a planar film formed from tetraethyl orthosilicate. In some embodiments, contacting the silicon oxide layer with argon plasma is performed with a bias power of 75 to 150 watts applied to the substrate. In some embodiments, contacting the silicon oxide layer with argon plasma is performed with at a pressure of about 30 to about 50 milliTorr. In some embodiments, contacting the silicon oxide layer with argon plasma is performed for a duration of 5 seconds to about 1 minute. in embodiments. contacting the silicon oxide layer with argon plasma is performed with argon supplied to the substrate at a flow rate between 50 and 150 sccm.

FIG. 8 is a flow diagram of a method 800 of forming a semiconductor film stack in accordance with the present disclosure. In embodiments, a method of forming a semiconductor film stack, includes at 802 contacting a silicon oxide layer disposed atop a silicon oxycarbide low-k dielectric layer with argon plasma under conditions sufficient to clean the silicon oxide layer, wherein the silicon oxide layer and silicon oxycarbide low-k dielectric layer are disposed upon a substrate and within a film stack. In embodiments, the silicon oxide layer comprises a planar film formed from tetraethyl orthosilicate. In some embodiments, contacting the silicon oxide layer with argon plasma is performed with a bias power of 75 to 150 watts applied to the substrate. In some embodiments, contacting the silicon oxide layer with argon plasma is performed with at a pressure of about 30 to about 50 milliTorr. In some embodiments, contacting the silicon oxide layer with argon plasma is performed for a duration of 5 seconds to about 1 minute. In embodiments, contacting the silicon oxide layer with argon plasma is performed with argon supplied to the substrate at a flow rate between 50 and 150 sccm.

In embodiments, the semiconductor film stack such as film stack shown in FIG. 2B includes a plurality of layers such as (nitride layer 240, oxide layer 220, low-k dielectric layer 210 and substrate 200), wherein each layer of the plurality of layers has a planar or substantially planar shape. For example, each layer of the plurality of layers is configured such that the surface of one layer is in a parallel or substantially parallel configuration to the adjacent surface of the adjacent layer. For example, in embodiments, the top layer of oxide layer 220 is configured to be in a parallel or substantially parallel configuration to the bottom surface of nitride layer 240.

While the foregoing is directed to embodiments of the present disclosure, other and further embodiments of the disclosure may be devised without departing from the basic scope thereof.

1. A method of reducing arcing of a silicon oxide layer in a film stack, comprising:
depositing a silicon oxide layer having a top surface atop a low-k dielectric layer, wherein the silicon oxide layer and low-k dielectric layer are disposed upon a substrate and within a film stack;
contacting the silicon oxide layer with argon plasma in an amount sufficient to clean the silicon oxide layer; and
depositing a nitride layer atop the silicon oxide layer.

2. The method of claim 1, wherein the silicon oxide layer comprises silicon oxide or silicon dioxide formed from an organosilicon compound.

3. The method of claim 1, wherein contacting the silicon oxide layer with argon plasma is performed with a bias power of 75 to 150 watts applied to the substrate.

4. The method of claim 1, wherein contacting the silicon oxide layer with argon plasma is performed with at a pressure of about 30 to about 50 milliTorr.

5. The method of claim 1, wherein contacting the silicon oxide layer with argon plasma is performed for a duration of 5 seconds to about 1 minute.

6. The method of claim 1, wherein contacting the silicon oxide layer with argon plasma is performed with argon supplied to the substrate at a flow rate between 50 and 150 sccm.

7. The method of claim 1, wherein the silicon oxide layer is a planar film.

8. The method of claim 1, wherein subsequent to depositing the nitride layer atop the silicon oxide layer, the silicon oxide layer is a substantially planar film.

9. The method of claim 8, wherein the nitride layer is titanium nitride.

10. The method of claim 8, wherein the nitride layer is deposited atop the silicon oxide layer at a pressure of about 150 to about 400 milliTorr.

11. The method of claim 8, wherein the nitride layer is deposited atop the silicon oxide layer at a pressure of about 300 to about 400 milliTorr.

12. The method of claim 8, wherein the nitride layer is deposited atop the silicon oxide layer under a power of about 18 to about 30 kilowatts.

13. The method of claim 8, wherein the nitride layer is deposited atop the silicon oxide layer at a temperature greater than 350 degrees Celsius.

14. A method of cleaning a silicon oxide layer in a film stack, comprising:
contacting a silicon oxide layer disposed atop a silicon oxycarbide low-k dielectric layer with argon plasma under conditions sufficient to clean the silicon oxide layer, wherein the silicon oxide layer and silicon oxycarbide low-k dielectric layer are disposed upon a substrate and within a film stack.

15. The method of claim 14, wherein the silicon oxide layer comprises a planar film formed from tetraethyl orthosilicate.

16. The method of claim 14, wherein contacting the silicon oxide layer with argon plasma is performed with a bias power of 75 to 150 watts applied to the substrate.

17. The method of claim 14, wherein contacting the silicon oxide layer with argon plasma is performed with at a pressure of about 30 to about 50 milliTorr.

18. The method of claim 14, wherein contacting the silicon oxide layer with argon plasma is performed for a duration of 5 seconds to about 1 minute.

19. The method of claim 14, wherein contacting the silicon oxide layer with argon plasma is performed with argon supplied to the substrate at a flow rate between 50 and 150 sccm.

20. A method of forming a semiconductor film stack, comprising:
contacting a silicon oxide layer disposed atop a silicon oxycarbide low-k dielectric layer with argon plasma under conditions sufficient to clean the silicon oxide layer, wherein the silicon oxide layer and silicon oxycarbide low-k dielectric layer are disposed upon a substrate and within a film stack.
